(19) United States
(12) Patent Application Publication
(10) Pub. No.: US 2014/0091364 A1
(43) Pub. Date: Apr. 3, 2014

(54) COMPOUND SEMICONDUCTOR DEVICE AND METHOD OF MANUFACTURING THE SAME

(71) Applicant: FUJITSU LIMITED, Kawasaki-shi (JP)

(72) Inventors: Kenji IMANISHI, Atsugi (JP); Atsushi YAMADA, Isehara (JP); Tetsuro ISHIGURO, Kawasaki (JP); Toyoo MIYAJIMA, Isehara (JP)

(73) Assignee: FUJITSU LIMITED, Kawasaki-shi (JP)

(21) Appl. No.: 13/956,867

(22) Filed: Aug. 1, 2013

(30) Foreign Application Priority Data
Sep. 28, 2012 (JP) 2012-217756

(51) Int. Cl. H01L 29/778; H01L 29/66

(52) U.S. Cl. CPC H01L 29/778; H01L 29/66431
USPC 257/194; 438/172

(57) ABSTRACT

An AlGaN/GaN HEMT includes: an electron transit layer; an electron supply layer formed above the electron transit layer; and a gate electrode formed above the electron supply layer, wherein a p-type semiconductor region is formed only at a site of the electron transit layer which is contained in a region below the gate electrode.

### CROSS-REFERENCE TO RELATED APPLICATION

This application is based upon and claims the benefit of priority of the prior Japanese Patent Application No. 2012-217756, filed on Sep. 28, 2012, the entire contents of which are incorporated herein by reference.

### FIELD

The embodiments discussed herein are directed to a compound semiconductor device and a method of manufacturing the same.

### BACKGROUND

There is considered application of a nitride semiconductor to a semiconductor device with high breakdown-voltage and high output power, utilizing characteristics such as high saturation electron velocity and wide band gap. For example, the band gap of GaN as the nitride semiconductor is 3.4 eV, which is larger than the band gap of Si (1.1 eV) and the band gap of GaAs (1.4 eV), and thus GaN has high breakdown electric field intensity. Accordingly, GaN is quite promising as a material of a semiconductor device for power supply which obtains high voltage operation and high output power.

As a device using the nitride semiconductor, there have been made numerous reports on a field effect transistor, particularly a high electron mobility transistor (HEMT). For example, among GaN-based HEMTs (GaN-HEMTs), AlGaN/GaN.HEMT using GaN as an electron transit layer and AlGaN as an electron supply layer is attracting attention. In the AlGaN/GaN.HEMT, a strain resulted from a lattice constant difference between GaN and AlGaN occurs in AlGaN. Two-dimensional electron gas (2DEG) of high concentration is obtained from piezoelectric polarization caused by the strain and spontaneous polarization of AlGaN. Accordingly, the AlGaN/GaN.HEMT is expected as a high efficiency switch element and a high-withstand-voltage electric power device for electric vehicle, or the like.
Patent Document 1: Japanese Laid-open Patent Publication No. 2007-294598
Patent Document 2: Japanese Laid-open Patent Publication No. 2009-71270
Patent Document 3: Japanese Laid-open Patent Publication No. 2010-199409

For a nitride semiconductor device, a technology of locally controlling the generation amount of 2DEG is required. For example, in the case of HEMT, a so-called normally-off operation in which no current flows at voltage off is desired from a point of view of so-called fail-safe. To this end, it is necessary to devise to suppress the generation amount of 2DEG below the gate electrode at voltage off.

As one of techniques for realizing a GaN HEMT performing normally-off operation, a technique is proposed which forms a p-type GaN layer on an electron supply layer to cancel 2DEG at a site corresponding to a position below a p-type GaN layer for the normally-off operation. In this technique, p-type GaN is grown, for example, on the whole surface of AlGaN that will be the electron supply layer, the p-type GaN is dry etched in a manner to remain on a formation scheduled site for a gate electrode to form the p-type GaN layer, and the gate electrode is formed thereon.

As described above, dry etching is used for patterning of the p-type GaN. This dry etching damages the surface layer of the electron supply layer arranged under the p-type GaN, and the etching damage is introduced into an access region of the GaN HEMT. This brings about a problem of increases on-resistance because of increase of sheet resistance (Rₛₕ) and contact resistance (ρₜ). Damages also generate defects snd traps, causing instability in operation.

### SUMMARY

An aspect of a compound semiconductor device includes: an electron transit layer; an electron supply layer formed above the electron transit layer; and an electrode formed above the electron supply layer, wherein a p-type semiconductor region is formed only at a site of the electron transit layer which is contained in a region below the electrode.

An aspect of a method of manufacturing a compound semiconductor device includes: forming an electron transit layer; forming a p-type semiconductor region only at an electrode formation scheduled site of the electron transit layer; forming an electron supply layer above the electron transit layer; and forming an electrode at a site above the electron supply layer which contains the p-type semiconductor region.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A to FIG. 1C are schematic cross-sectional views illustrating a method of manufacturing an AlGaN/GaN HEMT according to a first embodiment in order of processes;

FIG. 2A to FIG. 2C are schematic cross-sectional views, subsequent to FIG. 1A to FIG. 1C, illustrating the method of manufacturing the AlGaN/GaN HEMT according to the first embodiment in order of processes;

FIG. 3A to FIG. 3C are schematic cross-sectional views illustrating a method of manufacturing an AlGaN/GaN HEMT according to a second embodiment in order of processes;

FIG. 4A to FIG. 4C are schematic cross-sectional views, subsequent to FIG. 3A to FIG. 3C, illustrating the method of manufacturing the AlGaN/GaN HEMT according to the second embodiment in order of processes;

FIG. 5A to FIG. 5C are schematic cross-sectional views illustrating a method of manufacturing an AlGaN/GaN HEMT according to a third embodiment;

FIG. 6A and FIG. 6B are schematic cross-sectional views, subsequent to FIG. 5A to FIG. 5C, illustrating the method of manufacturing the AlGaN/GaN HEMT according to the third embodiment in order of processes;

FIG. 7A and FIG. 7B are schematic cross-sectional views, subsequent to FIG. 6A and FIG. 6B, illustrating the method of manufacturing the AlGaN/GaN HEMT according to the third embodiment in order of processes;

FIG. 8A to FIG. 8C are schematic cross-sectional views illustrating main processes in a method of manufacturing an AlGaN/GaN HEMT according to a fourth embodiment;

FIG. 9A and FIG. 9B are schematic cross-sectional views illustrating a method of manufacturing an AlGaN/GaN HEMT according to a fifth embodiment in order of processes;

FIG. 10A and FIG. 10B are schematic cross-sectional views, subsequent to FIG. 9A and FIG. 9B, illustrating the method of manufacturing the AlGaN/GaN HEMT according to the fifth embodiment in order of processes;

FIG. 11 is a connection diagram illustrating a schematic configuration of a power supply device according to a sixth embodiment; and

FIG. 12 is a connection diagram illustrating a schematic configuration of a high-frequency amplifier according to a seventh embodiment.

### DESCRIPTION OF EMBODIMENTS

Hereinafter, embodiments will be described in detail with reference to the drawings. In the following embodiments, a structure of a compound semiconductor device will be described along with a method of manufacturing the compound semiconductor device.

Note that, in the following drawings, some constituent members are not illustrated with relatively accurate size and thickness for convenience of illustration.

### First Embodiment

In this embodiment, an AlGaN/GaN HEMT is disclosed as the compound semiconductor device.

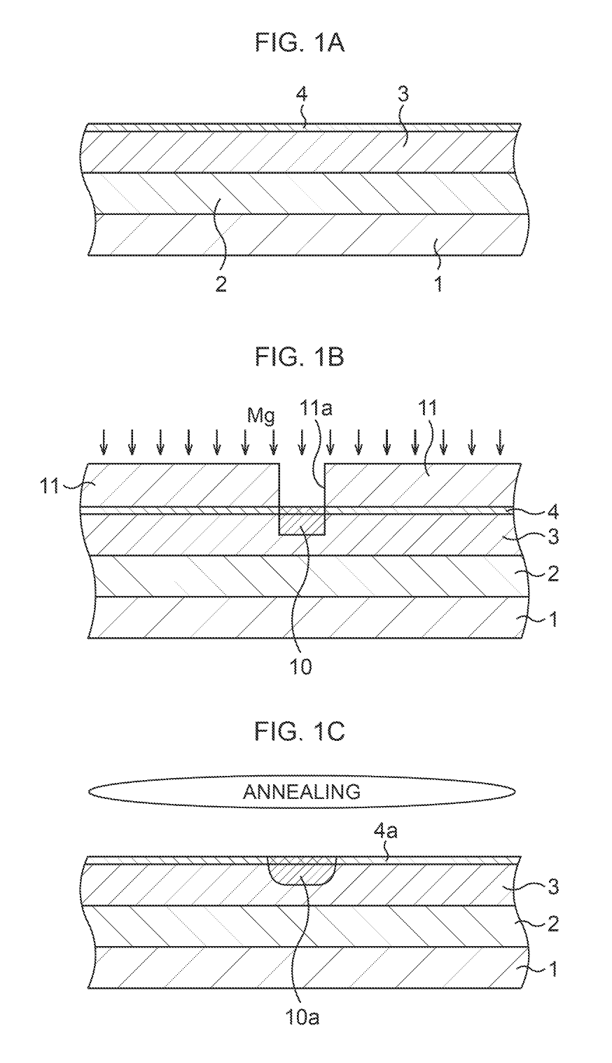

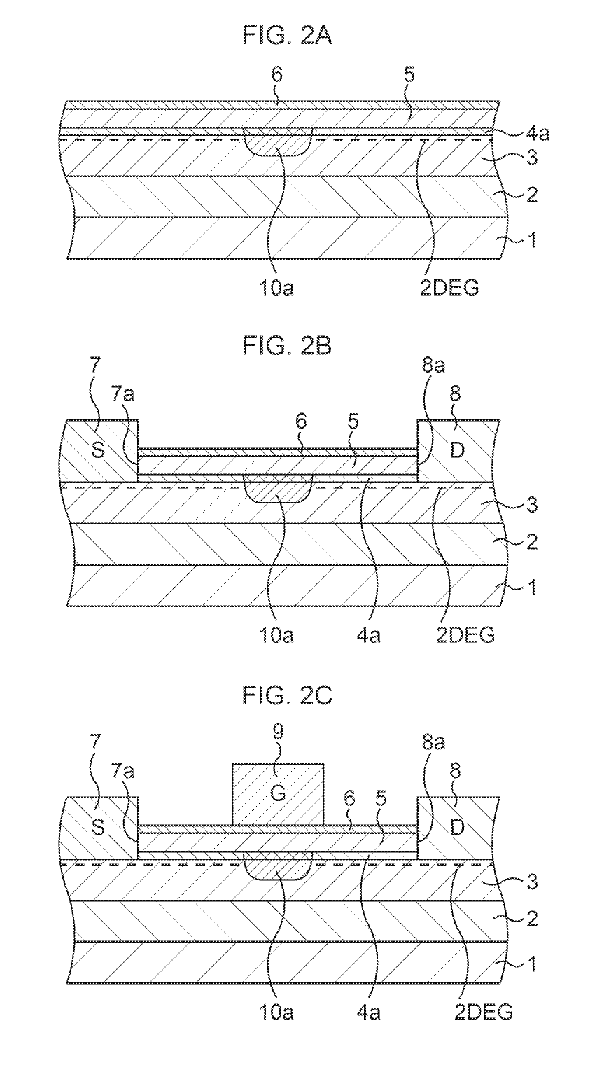

FIG. 1A to FIG. 1C and FIG. 2A to FIG. 2C are schematic cross-sectional views illustrating a method of manufacturing the AlGaN/GaN HEMT according to the first embodiment in order of processes.

First, as illustrated in FIG. 1A, a buffer layer 2, an electron transit layer 3, and a spacer layer 4 as layers of compound semiconductors are formed in order on, for example, a resistive Si substrate 1 being a growth substrate. As the growth substrate, a sapphire substrate, a GaAs substrate, a SiC substrate, a GaN substrate or the like may be used instead of the Si substrate. The conductivity of the substrate may be either resistive or conductive.

More specifically, on the Si substrate 1, the layers of the following compound semiconductors are epitaxially grown by, for example, an MOVPE (Metal Organic Vapor Phase Epitaxy) method. An MBE (Molecular Beam Epitaxy) method or the like may be used instead of the MOVPE method.

The buffer layer 2 is formed by growing AlN to a thickness of, for example, about 10 nm to 2000 nm on the Si substrate 1. The electron transit layer 3 is formed by growing i(intentionally undoped)-GaN to a thickness of, for example, about 1000 nm to 3000 nm. The spacer layer 4 is formed by growing i-AlGaN to a thickness of about 5 nm or less, for example, about 2 nm. As the spacer layer, i-InAlN or i-InAlGaN may be formed instead of i-AlGaN. Further, the spacer layer 4 is not formed in some cases.

For growth of AlN, mixed gas of trimethylaluminum (TMAl) gas being an Al source and ammonia (NH₃) gas is used as a source gas. For growth of GaN, mixed gas of trimethylgallium (TMGa) gas being a Ga source and NH₃ gas is used as a source gas. For growth of AlGaN, mixed gas of TMAl gas being an Al source, TMGa gas being a Ga source, and NH₃ gas is used as a source gas. According to the compound semiconductors to be grown, whether or not to supply the TMAl gas and the TMGa gas and flow rates thereof are appropriately set. The flow rate of the NH₃ gas being a common source is set to about 100 sccm to about 100 slm. Further, growth pressure is set to about 50 Torr to about 300 Torr, and growth temperature is set to about 800° C. to about 1200° C.

Subsequently, as illustrated in FIG. 1B, a p-type semiconductor region 10 is formed in the electron transit layer 3 and the spacer layer 4.

More specifically, first, a resist is applied on or above the electron transit layer 3 and processed by lithography to form a resist mask 11 having an opening 11a. Instead of the resist mask 11, a hard mask of SiN or the like may be formed. The resist mask 11 exposes, in the opening 11a, a site of the electron transit layer 3 corresponding to a formation scheduled site for a gate electrode. In the p-type semiconductor region, the range of a p-type acceptor (p-type impurity) is enlarged by subsequent annealing. In this embodiment, the opening 11a is formed in expectation of the enlargement so that the width of the enlarged p-type semiconductor region becomes smaller than the width (gate length) of the formation scheduled site for the gate electrode. The opening 11a is formed to be appropriately narrower than a formation scheduled range for the gate electrode so as to be contained in the formation scheduled range for the gate electrode.

Next, a p-type impurity, here, Mg is ion-implanted into the spacer layer 4 and the electron transit layer 3 using the resist mask 11. A doping concentration of Mg is set to about 1×10¹⁸/cm³ to about 1×10²⁰/cm³, for example, set to about 1×10¹⁹/cm³. As the p-type impurity, Zn, Be, Cd, C (carbon) or the like may be used instead of Mg. By this ion implantation, Mg is introduced into the spacer layer 4 and the electron transit layer 3 through the opening 11a to form the p-type semiconductor region 10. Mg introduced into a portion of the spacer layer 4 in the p-type semiconductor region 10 is generally lower in concentration than that into a portion of the electron transit layer 3.

Thereafter, the resist mask 11 is removed by ashing, chemical treatment or the like.

Subsequently, as illustrated in FIG. 1C, annealing is applied to the Si substrate 1.

More specifically, the Si substrate 1 is set in a chamber for MOVPE and subjected to annealing by keeping it at a relatively high temperature, for example, about 1000° C. This repairs crystal defects in the p-type semiconductor region 10 due to the ion implantation and activates the introduced Mg. Along with that, the annealing at high temperature thermally desorbs a GaN component from AlGaN of the spacer layer 4, so that the spacer layer 4 becomes AlGaN having a high Al composition. The p-type semiconductor region after the annealing is denoted by 10a, and the spacer layer after the annealing is denoted by 4a.

Because the p-type impurity is diffused by the annealing as described above, the range of the p-type semiconductor region 10a is enlarged to be larger than that of the p-type semiconductor region 10 before the annealing. Also after the enlargement of the range, the p-type semiconductor region 10a is formed to be contained in the formation scheduled range for the gate electrode and appropriately narrower than the formation scheduled range. This enables two-dimensional electron gas (2DEG) only at a portion aligned with and under the gate electrode of the 2DEG to surely disappear in the AlGaN/GaN HEMT.

In the case where the spacer layer 4 is not formed, when annealing is performed on the p-type semiconductor region 10 with the surface of the electron transit layer 3 exposed, some region of GaN electron transit layer 3 possibly thermally desorbs. In this embodiment, since the annealing is performed with the electron transit layer 3 covered with the spacer layer 4, thermal desorption of GaN of the electron transit layer 3 is suppressed. The annealing forms the spacer layer into the spacer layer 4a of AlGaN with a high Al composition and therefore increases the concentration of 2DEG generated in the vicinity of the surface of the electron transit layer 3. Further, the existence of the spacer layer 4a of AlGaN with a high Al composition prevents Mg in the p-type semiconductor region 10a from diffusing upward in the AlGaN/GaN HEMT. In this embodiment, the portion of the spacer layer 4a in the p-type semiconductor region 10a is lower in Mg concentration than the portion of the electron transit layer 3 in the p-type semiconductor region 10a. This surely suppresses the upward diffusion of Mg in the p-type semiconductor region 10a. Note that even if a crystal defect due to the ion implantation of Mg remains in the portion of the spacer layer 4a in the p-type semiconductor region 10a, there is no problem in terms of element operation because the volume ratio of the spacer layer 4a to a gate depletion layer is very small.

Subsequently, as illustrated in FIG. 2A, an electron supply layer 5 and a protective layer 6 are formed in order.

More specifically, the electron supply layer 5 and the protective layer 6 of the following semiconductors are epitaxially grown (regrown) in order on the spacer layer 4 again by the MOVPE method.

The electron supply layer 5 is formed by growing n-AlGaN to a thickness of, for example, about 20 nm on the spacer layer 4. As the electron supply layer, i-AlGaN may be formed. For growth of AlGaN, mixed gas of TMAl being an Al source, TMGa gas being a Ga source, and NH₃ gas is used as a source gas. The protective layer 6 is formed by growing n-GaN to a thickness of, for example, about 2 nm to about 10 nm. For growth of GaN, mixed gas of TMGa gas being a Ga source and NH₃ gas is used as a source gas. Regrowth temperatures of these compound semiconductors are set to about 850° C. to about 950° C.

In order to grow AlGaN as an n-type, that is, to form the electron supply layer 5 (n-AlGaN), an n-type impurity is added to the source gas of AlGaN. In order to grow GaN as an n-type, that is, to form the protective layer 6 (n-GaN), an n-type impurity is added to the source gas of GaN. Here, for example, silane (SiH₄) gas containing, for example, Si is added to the source gas at a predetermined flow rate, thereby doping AlGaN with Si. A doping concentration of Si is set to about 1×10¹⁷/cm³ to about 1×10²⁰/cm³, for example, set to about 3×10¹⁸/cm³.

Two-dimensional electron gas (2DEG) is generated in the vicinity of an interface of the electron transit layer 3 with the electron supply layer 5 (to be exact, the spacer layer 4a). The 2DEG is generated from piezoelectric polarization due to strain resulted from a lattice constant difference between the compound semiconductor (here, GaN) of the electron transit layer 3 and the compound semiconductor (here, AlGaN) of the electron supply layer 5 as well as from spontaneous polarization of the electron transit layer 3 and the electron supply layer 5. In this embodiment, 2DEG disappears only at a site of the p-type semiconductor region 10a and 2DEG of high concentration is generated at the other site, in the vicinity of the interface of the electron transit layer 3.

Subsequently, element isolation structures are formed.

More specifically, argon (Ar), for instance, is implanted into element isolation regions on the protective layer 6. Thus, the element isolation structures are formed. The element isolation structures demarcate an active region on the protective layer 6.

Incidentally, the element isolation may be performed using, instead of the above implantation method, another known method, for example, an STI (Shallow Trench Isolation) method or the like. In this event, for example, chlorine-based etching gas is used for dry etching of the compound semiconductor.

Subsequently, as illustrated in FIG. 2B, a source electrode 7 and a drain electrode 8 are formed.

More specifically, electrode recesses 7a, 8a are first formed at formation scheduled sites for the source electrode and the drain electrode.

A resist is applied on the surface of the protective layer 6. The resist is processed by lithography to form openings in the resist which expose the surface of the protective layer 6 corresponding to the formation scheduled sites for the source electrode and the drain electrode. Thus, a resist mask having these openings is formed. Instead of forming the resist mask, a hard mask of, for example, SiN may be formed.

Using this resist mask, the formation scheduled sites of the protective layer 6, the electron supply layer 5 and the spacer layer 4a for the source electrode and the drain electrode are dry etched and removed until the surface of the electron transit layer 3 is exposed. Thus, the electrode recesses 7a, 8a are formed, which expose the formation scheduled sites of the electron transit layer 3 for the source electrode and the drain electrode. As for etching conditions, for example, inert gas such as Ar and chlorine-based gas such as Cl₂ are used as etching gas, flow rate of Cl₂ is set to about 30 sccm, pressure is set to 2 Pa, and RF input power is set to 20 W for instance. Note that the electrode recesses 7a, 8a may be formed by performing the etching to a level slightly deeper than the surface of the electron transit layer 3. The electrode recesses 7a, 8a may be formed by performing the etching to a halfway of the electron supply layer 5.

The resist mask is removed by ashing, chemical treatment or the like.

Next, a resist mask for forming the source electrode and the drain electrode is formed. Here, for example, an eaves structure two-layer resist is used, which is suitable for a vapor deposition method and a lift-off method. This resist is applied on the protective layer 6, and openings for exposing the electrode recesses 7a, 8a are formed. Thus, the resist mask having these openings is formed.

Using this resist mask, Ta/Al for example is deposited as an electrode material by the vapor evaporation method for example, on the resist mask including the inside of the openings for exposing the electrode recesses 7a, 8a. The thickness of Ta is about 20 nm, and the thickness of Al is about 200 nm. By the lift-off method, the resist mask and Ta/Al deposited thereon are removed. Thereafter, the Si substrate 1 is heat treated at a temperature of about 400° C. to about 1000° C., for example about 600° C., in a nitrogen atmosphere, for example, thereby bringing the remaining Ta/Al into ohmic contact with the electron transit layer 3. As long as the ohmic contact of Ta/Al with the electron transit layer 3 can be obtained, there may be cases where the heat treatment is unnecessary. Thus, the source electrode 7 and the drain electrode 8 are formed such that the electrode recesses 7a, 8a are filled with a part of the electrode material.

Subsequently, as illustrated in FIG. 2C, a gate electrode 9 is formed.

More specifically, first, a resist mask for forming the gate electrode is formed. Here, for example, an eaves structure two-layer resist is used, which is suitable for a vapor deposition method and a lift-off method. This resist is applied on the protective layer 6, and an opening for exposing a formation scheduled site for the gate electrode on the protective layer 6 is formed. Thus, the resist mask having the opening is formed.

Using this resist mask, Ni/Au for example is deposited as an electrode material by the vapor deposition method for example, on the resist mask including a part of the surface of the protective layer 6 exposed in the opening. The thickness of Ni is about 30 nm, and the thickness of Au is about 400 nm. By the lift-off method, the resist mask and Ni/Au deposited thereon are removed. Thus, the gate electrode 9 is formed on the protective layer 6. The gate electrode 9 is in Schottky contact with the protective layer 6. The p-type semiconductor region 10a has a width smaller than the gate length of the gate electrode 9 and is aligned with the gate electrode 9 below the gate electrode 9. Note that a gate insulating film may be existed under the gate electrode 9.

Thereafter, through processes such as forming wirings connected to the source electrode 7, the drain electrode 8, and the gate electrode 9 and so on, the AlGaN/GaN.HEMT according to this embodiment is formed.

In this embodiment, the p-type semiconductor region 10a that raises the energy band is disposed only at a site of the electron transit layer 3 (and the spacer layer 4) which is aligned with and below the gate electrode 9. The p-type semiconductor region 10a is locally high in p-type impurity concentration (Mg concentration) both in a current conduction direction and in a stack direction of GaN crystals.

Since the etching of the electron transit layer 3 is unnecessary when forming the p-type semiconductor region 10a, the sheet resistance and the contact resistance are reduced to achieve a stable operation.

In this embodiment, the above structure allows 2DEG to disappear only at a site of the p-type semiconductor region 10a so as to surely achieve Normally Off.

In the electron transit layer 3, the p-type semiconductor region 10a is formed only at a site which is contained in a region below the gate electrode 9. Since the protective layer 6 and the electron supply layer 5 directly under the gate electrode 9 contain no p-type impurity, the on-voltage can be controlled to an appropriate value, thereby greatly improving the element reliability.

As described above, in this embodiment, a highly reliable AlGaN/GaN HEMT is realized which reduces the sheet resistance and the contact resistance to stabilize the operation and improve the device performance so as to surely achieve Normally Off.

### Second Embodiment

This embodiment discloses an AlGaN/GaN HEMT as a compound semiconductor device as in the first embodiment but is different from the first embodiment in that the formation state of the p-type semiconductor region is slightly different. Note that the same constituent members and so on as those in the first embodiment will be denoted by the same reference signs, and a detailed description thereof will be omitted.

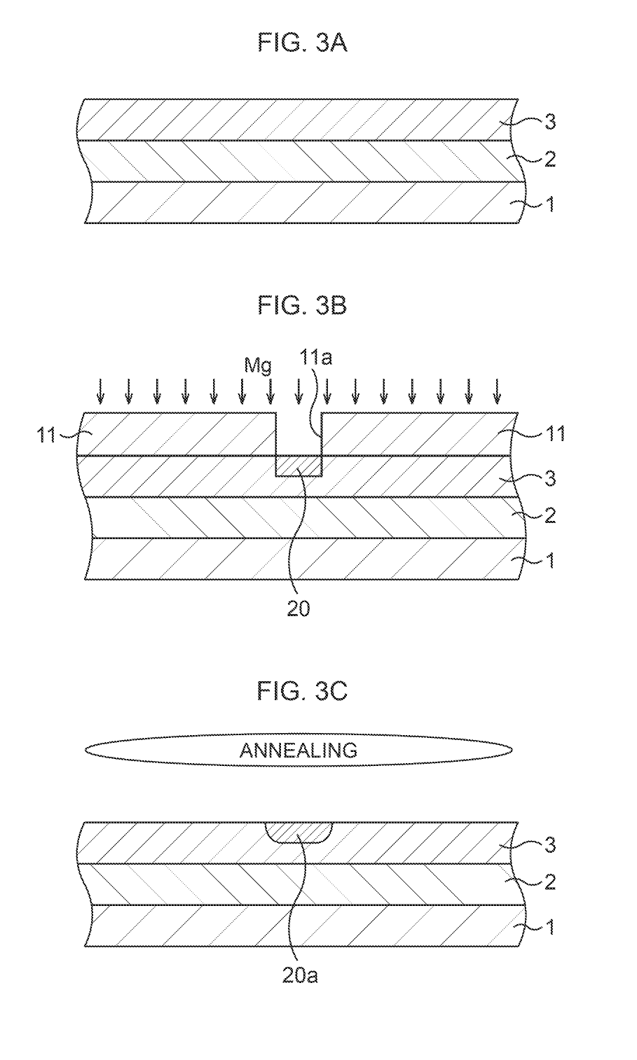

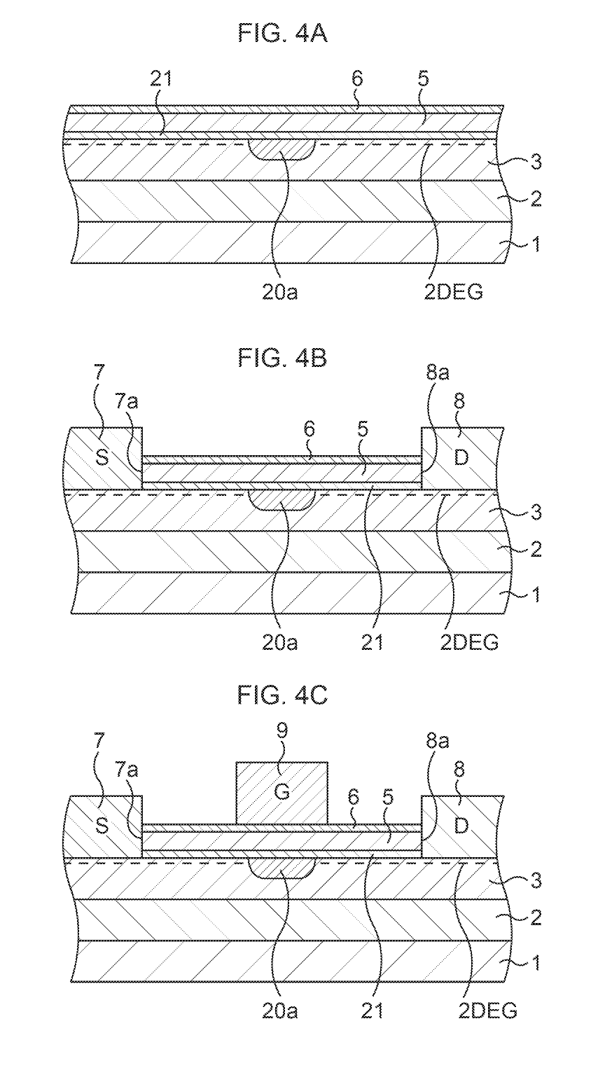

FIG. 3A to FIG. 3C and FIG. 4A to FIG. 4C are schematic cross-sectional views illustrating a method of manufacturing the AlGaN/GaN HEMT according to a second embodiment in order of processes.

First, as illustrated in FIG. 3A, a buffer layer 2 and an electron transit layer 3 as layers of compound semiconductors are formed in order on, for example, a semi-insulating Si substrate 1 being a growth substrate.

More specifically, on the Si substrate 1, the layers of the following compound semiconductors are epitaxially grown by, for example, an MOVPE method. An MBE method or the like may be used instead of the MOVPE method.

The buffer layer 2 is formed by growing AlN to a thickness of, for example, about 10 nm to 2000 nm on the Si substrate 1. The electron transit layer 3 is formed by growing i(intentionally undoped)-GaN to a thickness of, for example, about 1000 nm to 3000 nm.

For growth of AlN, mixed gas of TMAl gas being an Al source and NH₃ gas is used as a source gas. For growth of GaN, mixed gas of TMGa gas being a Ga source and NH₃ gas is used as a source gas. According to the compound semiconductors to be grown, whether or not to supply the TMAl gas and the TMGa gas and flow rates thereof are appropriately set. The flow rate of the NH₃ gas being a common source is set to about 100 sccm to about 100 slm. Further, growth pressure is set to about 50 Torr to about 300 Torr, and growth temperature is set to about 800° C. to about 1200° C.

Subsequently, as illustrated in FIG. 3B, a p-type semiconductor region 20 is formed in the electron transit layer 3.

More specifically, first, a resist is applied on the electron transit layer 3 and processed by lithography to form a resist mask 11 having an opening 11a. Instead of the resist mask 11, a hard mask of SiN or the like may be formed. The resist mask 11 exposes, in the opening 11a, a site of the electron transit layer 3 corresponding to a formation scheduled site for a gate electrode. In the p-type semiconductor region, the range of a p-type impurity is enlarged by subsequent annealing. In this embodiment, the opening 11a is formed in expectation of the enlargement so that the width of the enlarged p-type semiconductor region becomes smaller than the width (gate length) of the formation scheduled site for the gate electrode. The opening 11a is formed to be appropriately narrower than a formation scheduled range for the gate electrode so as to be contained in the formation scheduled range for the gate electrode.

Next, a p-type impurity, here, Mg is ion-implanted into the electron transit layer 3 using the resist mask 11. A doping concentration of Mg is set to about 1×10¹⁹/cm³ to about 1×10²⁰/cm³, for example, set to about 5×10¹⁹/cm³. As the p-type impurity, Zn, Be, Cd, C (carbon) or the like may be used instead of Mg. By this ion implantation, Mg is introduced into the electron transit layer 3 through the opening 11a to form the p-type semiconductor region 20.

Thereafter, the resist mask 11 is removed by ashing, chemical treatment or the like.

Subsequently, as illustrated in FIG. 3C, annealing is applied to the Si substrate 1.

More specifically, the Si substrate 1 is set in a chamber for MOVPE and subjected to annealing by keeping it at a relatively high temperature, for example, about 1000° C. This repairs crystal defects in the p-type semiconductor region 20 due to the ion implantation and activates the introduced Mg. The p-type semiconductor region after the annealing is denoted by 20a.

Because the p-type impurity is diffused by the annealing as described above, the range of the p-type semiconductor region 20a is enlarged to be larger than that of the p-type semiconductor region 20 before the annealing. Also after the enlargement of the range, the p-type semiconductor region 20a is contained in the formation scheduled range for the gate electrode and formed to be appropriately narrower than the formation scheduled range. This enables 2DEG only at a portion aligned with and under the gate electrode of the 2DEG to surely disappear in the AlGaN/GaN HEMT.

Subsequently, as illustrated in FIG. 4A, a spacer layer 21, an electron supply layer 5 and a protective layer 6 are formed in order.

More specifically, the spacer layer 21, the electron supply layer 5 and the protective layer 6 of the following semiconductors are epitaxially grown (regrown) in order on the electron transit layer 3 again by the MOVPE method.

The spacer layer 21 is formed by growing i-AlGaN to a thickness of about 5 nm or less, for example, about 2 nm on the electron transit layer 3. i-AlGaN of the spacer layer 21 is preferably formed to have a high Al composition, for example, into Al_{( )}Ga_{( )}. Forming the i-AlGaN of the spacer layer 21 with a high Al composition prevents Mg in the p-type semiconductor region 20a from diffusing upward in the AlGaN/GaN HEMT. As the spacer layer, i-InAlN or i-InAlGaN may be formed instead of i-AlGaN.

The electron supply layer 5 is formed by growing n-AlGaN to a thickness of, for example, about 20 nm on the spacer layer 21. As the electron supply layer, i-AlGaN may be formed. For growth of AlGaN, mixed gas of TMAl being an Al source, TMGa gas being a Ga source, and NH₃ gas is used as a source gas. The protective layer 6 is formed by growing n-GaN to a thickness of, for example, about 2 nm to about 10 nm. For growth of GaN, mixed gas of TMGa gas being a Ga source and NH₃ gas is used as a source gas. Regrowth temperatures of these compound semiconductors are set to about 800° C. to about 900° C.

In order to grow AlGaN as an n-type, that is, to form the electron supply layer 5 (n-AlGaN), an n-type impurity is added to the source gas of AlGaN. In order to grow GaN as an n-type, that is, to form the protective layer 6 (n-GaN), an n-type impurity is added to the source gas of GaN. Here, for example, silane (SiH₄) gas containing, for example, Si is added to the source gas at a predetermined flow rate, thereby doping AlGaN with Si. A doping concentration of Si is set to about 1×10¹⁸/cm³ to about 1×10²⁰/cm³, for example, set to about 3×10¹⁸/cm³.

Two-dimensional electron gas (2DEG) is generated in the vicinity of an interface of the electron transit layer 3 with the electron supply layer 5 (to be exact, the spacer layer 21). The 2DEG is generated from piezoelectric polarization due to strain resulted from a lattice constant difference between the compound semiconductor (here, GaN) of the electron transit layer 3 and the compound semiconductor (here, AlGaN) of the electron supply layer 5 as well as from spontaneous polarization of the electron transit layer 3 and the electron supply layer 5. In this embodiment, 2DEG disappears only at a site of the p-type semiconductor region 20a and 2DEG of high concentration is generated at the other site, in the vicinity of the interface of the electron transit layer 3.

Subsequently, element isolation structures are formed.

More specifically, argon (Ar), for instance, is implanted into element isolation regions on the protective layer 6. Thus, the element isolation structures are formed. The element isolation structures demarcate an active region on the protective layer 6.

Incidentally, the element isolation may be performed using, instead of the above implantation method, another known method, for example, an STI method or the like. In this event, for example, chlorine-based etching gas is used for dry etching of the compound semiconductors.

Subsequently, as illustrated in FIG. 4B, a source electrode 7 and a drain electrode 8 are formed.

More specifically, electrode recesses 7a, 8a are first formed at formation scheduled sites for the source electrode and the drain electrode.

A resist is applied on the surface of the protective layer 6. The resist is processed by lithography to form openings in the resist which expose the surface of the protective layer 6 corresponding to the formation scheduled sites for the source electrode and the drain electrode. Thus, a resist mask having these openings is formed. Instead of forming the resist mask, a hard mask of, for example, SiN may be formed.

Using this resist mask, the formation scheduled sites of the protective layer 6, the electron supply layer 5 and the spacer layer 21 for the source electrode and the drain electrode are dry etched and removed until the surface of the electron transit layer 3 is exposed. Thus, the electrode recesses 7a, 8a are formed, which expose the formation scheduled sites of the electron transit layer 3 for the source electrode and the drain electrode. As for etching conditions, for example, inert gas such as Ar and chlorine-based gas such as Cl₂ are used as etching gas, flow rate of Cl₂ is set to about 30 sccm, pressure is set to 2 Pa, and RF input power is set to 20 W for instance. Note that the electrode recesses 7a, 8a may be formed by performing the etching to a level slightly deeper than the surface of the electron transit layer 3.

The resist mask is removed by ashing, chemical treatment or the like.

Next, a resist mask for forming the source electrode and the drain electrode is formed. Here, for example, an eaves structure two-layer resist is used, which is suitable for a vapor deposition method and a lift-off method. This resist is applied on the protective layer 6, and openings for exposing the electrode recesses 7a, 8a are formed. Thus, the resist mask having these openings is formed.

Using this resist mask, Ta/Al for example is deposited as an electrode material by the vapor deposition method for example, on the resist mask including the inside of the openings for exposing the electrode recesses 7a, 8a. The thickness of Ta is about 20 nm, and the thickness of Al is about 200 nm. By the lift-off method, the resist mask and Ta/Al deposited thereon are removed. Thereafter, the Si substrate 1 is heat treated at a temperature of about 400° C. to about 1000° C., for example about 600° C., in a nitrogen atmosphere, for example, thereby bringing the remaining Ta/Al into ohmic contact with the electron transit layer 3. As long as the ohmic contact of Ta/Al with the electron transit layer 3 can be obtained, there may be cases where the heat treatment is unnecessary. Thus, the source electrode 7 and the drain electrode 8 are formed such that the electrode recesses 7a, 8a are filled with a part of the electrode material.

Subsequently, as illustrated in FIG. 4C, a gate electrode 9 is formed.

More specifically, first, a resist mask for forming the gate electrode is formed. Here, for example, an eaves structure two-layer resist is used, which is suitable for a vapor deposition method and a lift-off method. This resist is applied on the protective layer 6, and an opening for exposing a formation scheduled site for the gate electrode on the protective layer 6 is formed. Thus, the resist mask having the opening is formed.

Using this resist mask, Ni/Au for example is deposited as an electrode material by the vapor deposition method for example, on the resist mask including a part of the surface of the protective layer 6 exposed in the opening. The thickness of Ni is about 30 nm, and the thickness of Au is about 400 nm. By the lift-off method, the resist mask and Ni/Au deposited thereon are removed. Thus, the gate electrode 9 is formed on the protective layer 6. The gate electrode 9 is in Schottky contact with the protective layer 6. The p-type semiconductor region 20a has a width smaller than the gate length of the gate electrode 9 and is aligned with the gate electrode 9 below the gate electrode 9.

Thereafter, through processes such as forming wirings connected to the source electrode 7, the drain electrode 8, and the gate electrode 9 and so on, the AlGaN/GaN.HEMT according to this embodiment is formed.

In this embodiment, the p-type semiconductor region 20a that raises the energy band is disposed only at a site of the electron transit layer 3 which is aligned with and below the gate electrode 9. The p-type semiconductor region 20a is locally high in p-type impurity concentration (Mg concentration) both in a current conduction direction and in a stack direction of GaN crystals.

Since the etching of the electron transit layer 3 is unnecessary when forming the p-type semiconductor region 20a, the sheet resistance and the contact resistance are reduced to achieve a stable operation.

In this embodiment, the above structure allows 2DEG to disappear only at a site of the p-type semiconductor region 20a so as to surely achieve Normally Off.

In the electron transit layer 3, the p-type semiconductor region 20a is formed only at a site which is contained in a region below the gate electrode 9. Since the protective layer 6 and the electron supply layer 5 directly under the gate electrode 9 contain no p-type impurity, the on-voltage can be controlled to an appropriate value, thereby greatly improving the element reliability.

As described above, in this embodiment, a highly reliable AlGaN/GaN HEMT is realized which reduces the sheet resistance and the contact resistance to stabilize the operation and improve the device performance so as to surely achieve Normally Off.

### Third Embodiment

This embodiment discloses an AlGaN/GaN HEMT as a compound semiconductor device as in the first embodiment but is different from the first embodiment in that the formation state of the p-type semiconductor region is slightly different. Note that the same constituent members and so on as those in the first embodiment will be denoted by the same reference signs, and a detailed description thereof will be omitted.

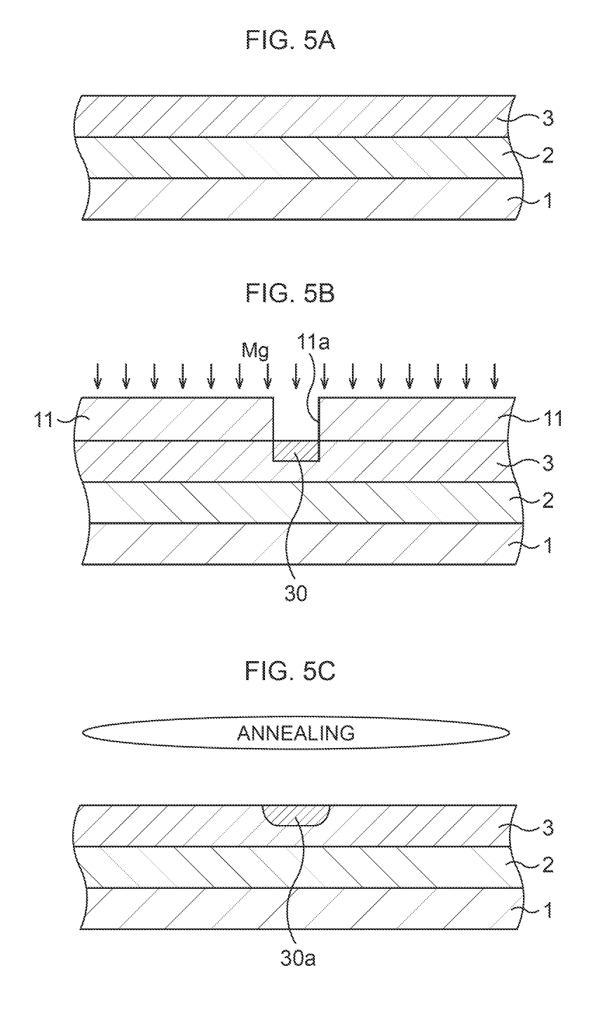

FIG. 5A to FIG. 5C to FIG. 7A and FIG. 7B are schematic cross-sectional views illustrating a method of manufacturing the AlGaN/GaN HEMT according to a third embodiment in order of processes.

First, as illustrated in FIG. 5A, a buffer layer 2 and an electron transit layer 3 as layers of compound semiconductors are formed in order on, for example, a semi-insulating Si substrate 1 being a growth substrate.

More specifically, on the Si substrate 1, the layers of the following compound semiconductors are epitaxially grown by, for example, an MOVPE method. An MBE method or the like may be used instead of the MOVPE method.

The buffer layer 2 is formed by growing AlN to a thickness of, for example, about 10 nm to 2000 nm on the Si substrate 1. The electron transit layer 3 is formed by growing i(intentionally undoped)-GaN to a thickness of, for example, about 1000 nm to 3000 nm.

For growth of AlN, mixed gas of TMAl gas being an Al source and NH₃ gas is used as a source gas. For growth of GaN, mixed gas of TMGa gas being a Ga source and NH₃ gas is used as a source gas. According to the compound semiconductors to be grown, whether or not to supply the TMAl gas and the TMGa gas and flow rates thereof are appropriately set. The flow rate of the NH₃ gas being a common source is set to about 100 sccm to about 100 slm. Further, growth pressure is set to about 50 Torr to about 300 Torr, and growth temperature is set to about 800° C. to about 1200° C.

Subsequently, as illustrated in FIG. 5B, a p-type semiconductor region 30 is formed in the electron transit layer 3.

More specifically, first, a resist is applied on the electron transit layer 3 and processed by lithography to form a resist mask 11 having an opening 11a. Instead of the resist mask 11, a hard mask of SiN or the like may be formed. The resist mask 11 exposes, in the opening 11a, a site of the electron transit layer 3 corresponding to a formation scheduled site for a gate electrode. In the p-type semiconductor region, the range of a p-type impurity is enlarged by subsequent annealing. In this embodiment, the opening 11a is formed in expectation of the enlargement so that the width of the enlarged p-type semiconductor region becomes smaller than the width (gate length) of the formation scheduled site for the gate electrode. The opening 11a is formed to be appropriately narrower than a formation scheduled range for the gate electrode so as to be contained in the formation scheduled range for the gate electrode.

Next, a p-type impurity, here, Mg is ion-implanted into the electron transit layer 3 using the resist mask 11. A doping concentration of Mg is set to about 1×10¹⁹/cm³ to about 1×10²⁰/cm³, for example, set to about 5×10¹⁹/cm³. As the p-type impurity, Zn, Be, Cd, C (carbon) or the like may be used instead of Mg. By this ion implantation, Mg is introduced into the electron transit layer 3 through the opening 11a to form the p-type semiconductor region 30.

Thereafter, the resist mask 11 is removed by ashing, chemical treatment or the like.

Subsequently, as illustrated in FIG. 5C, annealing is applied to the Si substrate 1.

More specifically, the Si substrate 1 is set in a chamber for MOVPE and subjected to annealing by keeping it at a relatively high temperature, for example, about 1000° C. This repairs crystal defects in the p-type semiconductor region 30 due to the ion implantation and activates the introduced Mg. The p-type semiconductor region after the annealing is denoted by 30a.

Because the p-type impurity is diffused by the annealing as described above, the range of the p-type semiconductor region 30a is enlarged to be larger than that of the p-type semiconductor region 30 before the annealing. Also after the enlargement of the range, the p-type semiconductor region 30a is contained in the formation scheduled range for the gate electrode and formed to be appropriately narrower than the formation scheduled range. This enables 2DEG only at a portion aligned with and under the gate electrode of the 2DEG to surely disappear in the AlGaN/GaN HEMT.

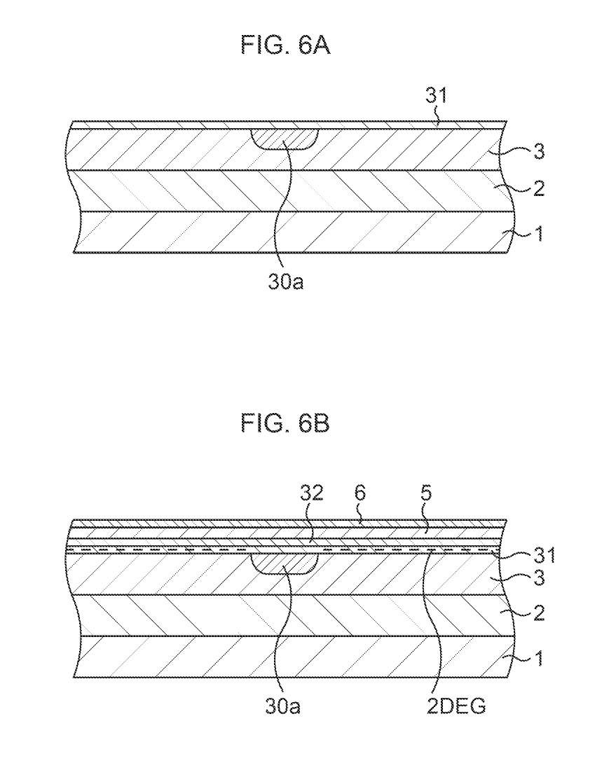

Subsequently, a regrowth layer 31 is formed as illustrated in FIG. 6A, and a spacer layer 32, an electron supply layer 5 and a protective layer 6 are subsequently formed in order as illustrated in FIG. 6B.

More specifically, the regrowth layer 31, the spacer layer 32, the electron supply layer 5 and the protective layer 6 are epitaxially grown (regrown) in order on the electron transit layer 3 again by the MOVPE method.

The regrowth layer 31 is formed on the electron transit layer 3, as a regrowth layer of the electron transit layer 3, by growing i-GaN, which is the same material as that of the electron transit layer 3, to a thickness of, for example, about 100 nm. Forming the regrowth layer 31 of i-GaN improves the mobility in the AlGaN/GaN HEMT. The electron transit layer 3 and the regrowth layer 31 are integrated to actually function as an electron transit layer. The upper surface of the p-type semiconductor region 30a is located at a site away from the surface of the electron transit layer in a depth direction (away by the thickness of the regrowth layer 31).

The spacer layer 32 is formed by growing i-AlGaN to a thickness of about 5 nm or less, for example, about 2 nm above the electron transit layer 3. i-AlGaN of the spacer layer 32 is preferably formed to be AlN or to have a high Al composition, for example, into Al_{0.8}Ga_{0.2}N. Forming the i-AlGaN of the spacer layer 32 with a high Al composition prevents Mg in the p-type semiconductor region 30a from diffusing upward in the AlGaN/GaN HEMT. As the spacer layer, i-InAlN or i-InAlGaN may be formed instead of i-AlGaN. The spacer layer 4 is not formed in some cases.

The electron supply layer 5 is formed by growing n-AlGaN to a thickness of, for example, about 20 nm on the spacer layer 32. As the electron supply layer, i-AlGaN may be formed. For growth of AlGaN, mixed gas of TMAl being an Al source, TMGa gas being a Ga source, and NH₃ gas is used as a source gas. The protective layer 6 is formed by growing n-GaN to a thickness of, for example, about 2 nm to about 10 nm. For growth of GaN, mixed gas of TMGa gas being a Ga source and NH₃ gas is used as a source gas. Regrowth temperatures of these compound semiconductors are set to about 850° C. to about 950° C.

In order to grow AlGaN as an n-type, that is, to form the electron supply layer 5 (n-AlGaN), an n-type impurity is added to the source gas of AlGaN. In order to grow GaN as an n-type, that is, to form the protective layer 6 (n-GaN), an n-type impurity is added to the source gas of GaN. Here, for example, silane (SiH₄) gas containing, for example, Si is added to the source gas at a predetermined flow rate, thereby doping AlGaN with Si. A doping concentration of Si is set to about 1×10¹⁸/cm³ to about 1×10²⁰/cm³, for example, set to about 3×10¹⁸/cm³.

Two-dimensional electron gas (2DEG) is generated in the vicinity of an interface of the regrowth layer 31 constituting the electron transit layer with the electron supply layer 5 (to be exact, the spacer layer 32). The 2DEG is generated from piezoelectric polarization due to strain resulted from a lattice constant difference between the compound semiconductor (here, GaN) of the electron transit layer and the compound semiconductor (here, AlGaN) of the electron supply layer 5 as well as from spontaneous polarization of the electron transit layer and the electron supply layer 5. In this embodiment, 2DEG disappears only at a site aligned with and above the p-type semiconductor region 30a and 2DEG of high concentration is generated at the other site, in the vicinity of the interface of the electron transit layer.

Subsequently, element isolation structures are formed.

More specifically, argon (Ar), for instance, is implanted into element isolation regions on the protective layer 6. Thus, the element isolation structures are formed. The element isolation structures demarcate an active region on the protective layer 6.

Incidentally, the element isolation may be performed using, instead of the above implantation method, another known method, for example, an STI method or the like. In this event, for example, chlorine-based etching gas is used for dry etching of the compound semiconductor.

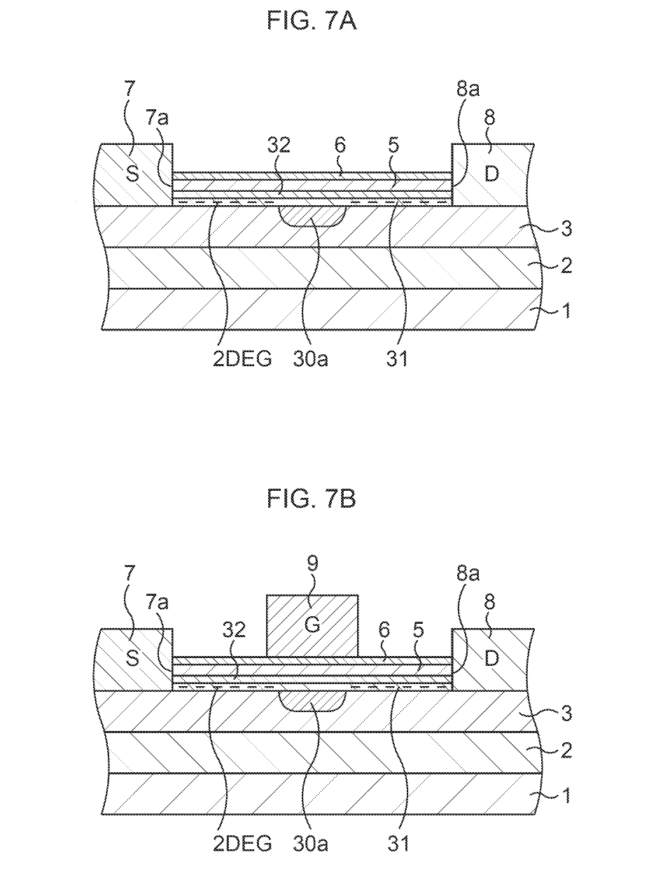

Subsequently, as illustrated in FIG. 7A, a source electrode 7 and a drain electrode 8 are formed.

More specifically, electrode recesses 7a, 8a are first formed at formation scheduled sites for the source electrode and the drain electrode.

A resist is applied on the surface of the protective layer 6. The resist is processed by lithography to form openings in the resist which expose the surface of the protective layer 6 corresponding to the formation scheduled sites for the source electrode and the drain electrode. Thus, a resist mask having these openings is formed. Instead of forming the resist mask, a hard mask of, for example, SiN may be formed.

Using this resist mask, the formation scheduled sites of the protective layer 6, the electron supply layer 5, the spacer layer 32 and the regrowth layer 31 for the source electrode and the drain electrode are dry etched and removed until the surface of the electron transit layer 3 is exposed. Thus, the electrode recesses 7a, 8a are formed, which expose the formation scheduled sites of the electron transit layer 3 for the source electrode and the drain electrode. As for etching conditions, for example, inert gas such as Ar and chlorine-based gas such as Cl₂ are used as etching gas, flow rate of Cl₂ is set to about 30 sccm, pressure is set to 2 Pa, and RF input power is set to 20 W for instance. Note that the electrode recesses 7a, 8a may be formed by performing the etching to a level slightly deeper than the surface of the electron transit layer 3.

The resist mask is removed by ashing, chemical treatment or the like.

Next, a resist mask for forming the source electrode and the drain electrode is formed. Here, for example, an eaves structure two-layer resist is used, which is suitable for a vapor deposition method and a lift-off method. This resist is applied on the protective layer 6, and openings for exposing the electrode recesses 7a, 8a are formed. Thus, the resist mask having these openings is formed.

Using this resist mask, Ta/Al for example is deposited as an electrode material by the vapor deposition method for example, on the resist mask including the inside of the openings for exposing the electrode recesses 7a, 8a. The thickness of Ta is about 20 nm, and the thickness of Al is about 200 nm. By the lift-off method, the resist mask and Ta/Al deposited thereon are removed. Thereafter, the Si substrate 1 is heat treated at a temperature of about 400° C. to about 1000° C., for example about 600° C., in a nitrogen atmosphere, for example, thereby bringing the remaining Ta/Al into ohmic contact with the electron transit layer 3. As long as the ohmic contact of Ta/Al with the electron transit layer 3 can be obtained, there may be cases where the heat treatment is unnecessary. Thus, the source electrode 7 and the drain electrode 8 are formed such that the electrode recesses 7a, 8a are filled with a part of the electrode material.

Subsequently, as illustrated in FIG. 7B, a gate electrode 9 is formed.

More specifically, first, a resist mask for forming the gate electrode is formed. Here, for example, an eaves structure two-layer resist is used, which is suitable for a vapor deposition method and a lift-off method. This resist is applied on the protective layer 6, and an opening for exposing a formation scheduled site for the gate electrode on the protective layer 6 is formed. Thus, the resist mask having the opening is formed.

Using this resist mask, Ni/Au for example is deposited as an electrode material by the vapor deposition method, for example, on the resist mask including a part of the surface of the protective layer 6 exposed in the opening. The thickness of Ni is about 30 nm, and the thickness of Au is about 400 nm. By the lift-off method, the resist mask and Ni/Au deposited thereon are removed. Thus, the gate electrode 9 is formed on the protective layer 6. The gate electrode 9 is in Schottky contact with the protective layer 6. The p-type semiconductor region 30a has a width smaller than the gate length of the gate electrode 9 and is aligned with the gate electrode 9 below the gate electrode 9.

Thereafter, through processes such as forming wirings connected to the source electrode 7, the drain electrode 8, and the gate electrode 9 and so on, the AlGaN/GaN.HEMT according to this embodiment is formed.

In this embodiment, the p-type semiconductor region 30a that raises the energy band is disposed only at a site of the electron transit layer 3 which is aligned with and below the gate electrode 9. The p-type semiconductor region 30a is locally high in p-type impurity concentration (Mg concentration) both in a current conduction direction and in a stack direction of GaN crystals.

Since the etching of the electron transit layer 3 is unnecessary when forming the p-type semiconductor region 30a, the sheet resistance and the contact resistance are reduced to achieve a stable operation.

In this embodiment, the above structure allows 2DEG to disappear only at a site of the regrowth layer 31 located on the p-type semiconductor region 30a so as to surely achieve Normally Off.

In the electron transit layer 3, the p-type semiconductor region 30a is formed only at a site which is contained in a region below the gate electrode 9. Since the protective layer 6 and the electron supply layer 5 directly under the gate electrode 9 contain no p-type impurity, the on-voltage can be controlled to an appropriate value, thereby greatly improving the element reliability.

As described above, in this embodiment, a highly reliable AlGaN/GaN HEMT is realized which reduces the sheet resistance and the contact resistance to stabilize the operation and improve the device performance so as to surely achieve Normally Off.

### Fourth Embodiment

This embodiment discloses an AlGaN/GaN HEMT as a compound semiconductor device as in the first embodiment but exemplifies a so-called MIS-type AlGaN/GaN HEMT in contrast to the Schottky-type AlGaN/GaN HEMT in the first embodiment.

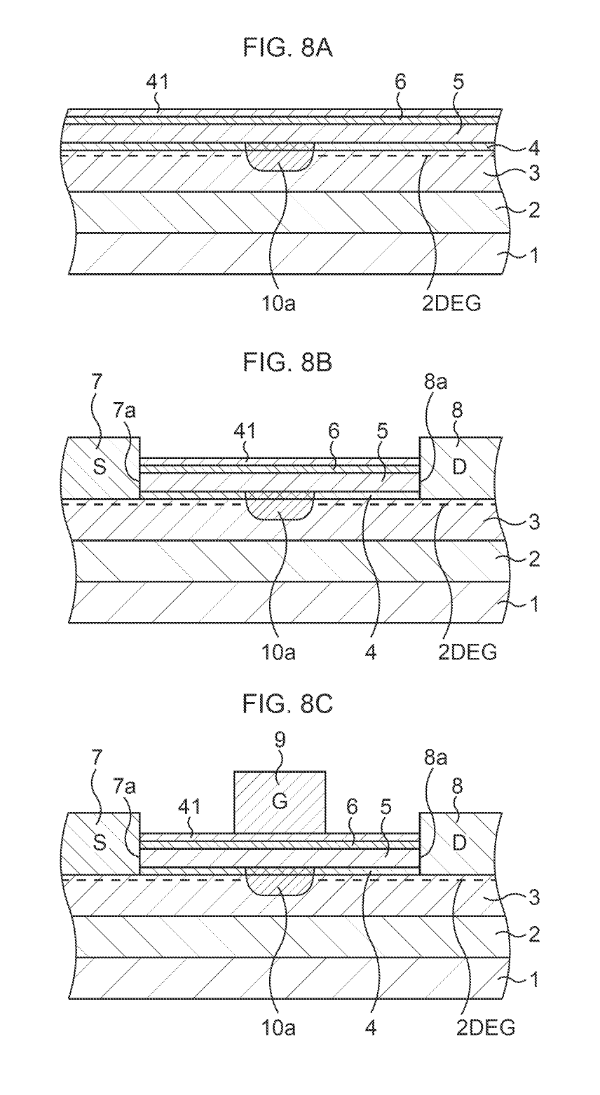

FIG. 8A to FIG. 8C are schematic cross-sectional views illustrating main processes in a method of manufacturing the AlGaN/GaN HEMT according to the fourth embodiment.

In this embodiment, first, formation processes in FIG. 1A to FIG. 2A and of element isolation structures are performed in order.

Subsequently, as illustrated in FIG. 8A, a gate insulating film 41 is formed on a protective layer 6.

More specifically, for example, Al₂O₃ is deposited as an insulating material on the protective layer 6. Al₂O₃ is deposited to a film thickness of about 2 nm to about 200 nm, here, about 10 nm, for example, by an ALD (Atomic Layer Deposition) method. Thus, the gate insulating film 41 is formed.

Incidentally, for the deposition of Al₂O₃, a plasma CVD method, a sputtering method, or the like, for instance, may be performed instead of the ALD method. Further, instead of depositing Al₂O₃, a nitride or an oxynitride of Al may be used. Besides, an oxide, a nitride, an oxynitride of Si, Hf, Zr, Ti, Ta, or W or a multilayer of appropriately selected ones from among these may be deposited to form the gate insulating film.

Subsequently, as illustrated in FIG. 8B, a source electrode 7 and a drain electrode 8 are formed.

More specifically, electrode recesses 7a, 8a are first formed at formation scheduled sites for the source electrode and the drain electrode.

A resist is applied on the surface of the gate insulating film 41. The resist is processed by lithography to form openings in the resist which expose the surface of the gate insulating film 41 corresponding to the formation scheduled sites for the source electrode and the drain electrode. Thus, a resist mask having these openings is formed. Instead of forming the resist mask, a hard mask of, for example, SiN may be formed.

Using this resist mask, the formation scheduled sites of the gate insulating film 41, the protective layer 6, an electron supply layer 5 and a spacer layer 4a for the source electrode and the drain electrode are dry etched and removed until the surface of the electron transit layer 3 is exposed. Thus, the electrode recesses 7a, 8a are formed, which expose the formation scheduled sites of the electron transit layer 3 for the source electrode and the drain electrode. As for etching conditions, for example, inert gas such as Ar and chlorine-based gas such as Cl₂ are used as etching gas, flow rate of Cl₂ is set to about 30 sccm, pressure is set to 2 Pa, and RF input power is set to 20 W for instance. Note that the electrode recesses 7a, 8a may be formed by performing the etching to a level slightly deeper than the surface of the electron transit layer 3.

The resist mask is removed by ashing, chemical treatment or the like.

Next, a resist mask for forming the source electrode and the drain electrode is formed. Here, for example, an eaves structure two-layer resist is used, which is suitable for a vapor deposition method and a lift-off method. This resist is applied on the gate insulating film 41, and openings for exposing the electrode recesses 7a, 8a are formed. Thus, the resist mask having these openings is formed.

Using this resist mask, Ta/Al for example is deposited as an electrode material by the vapor deposition method, for example, on the resist mask including the inside of the openings for exposing the electrode recesses 7a, 8a. The thickness of Ta is about 20 nm, and the thickness of Al is about 200 nm. By the lift-off method, the resist mask and Ta/Al deposited thereon are removed. Thereafter, the Si substrate 1 is heat treated at a temperature of about 400° C. to about 1000° C., for example about 600° C., in a nitrogen atmosphere, for example, thereby bringing the remaining Ta/Al into ohmic contact with the electron transit layer 3. As long as the ohmic contact of Ta/Al with the electron transit layer 3 can be obtained, there may be cases where the heat treatment is unnecessary. Thus, the source electrode 7 and the drain electrode 8 are formed such that the electrode recesses 7a, 8a are filled with a part of the electrode material.

Subsequently, as illustrated in FIG. 8C, a gate electrode 9 is formed.

More specifically, first, a resist mask for forming the gate electrode is formed. Here, for example, an eaves structure two-layer resist is used, which is suitable for a vapor deposition method and a lift-off method. This resist is applied on the gate insulating film 41, and an opening for exposing a formation scheduled site for the gate electrode on the gate insulating film 41 is formed. Thus, the resist mask having the opening is formed.

Using this resist mask, Ni/Au for example is deposited as an electrode material by the vapor deposition method, for example, on the resist mask including a part of the surface of the gate insulating film 41 exposed in the opening. The thickness of Ni is about 30 nm, and the thickness of Au is about 400 nm. By the lift-off method, the resist mask and Ni/Au deposited thereon are removed. Thus, the gate electrode 9 is formed on the gate insulating film 41. The p-type semiconductor region 10a has a width smaller than the gate length of the gate electrode 9 and is aligned with the gate electrode 9 below the gate electrode 9.

Thereafter, through processes such as forming wirings connected to the source electrode 7, the drain electrode 8, and the gate electrode 9 and so on, the MIS-type AlGaN/GaN.HEMT according to this embodiment is formed.

In this embodiment, the p-type semiconductor region 10a that raises the energy band is disposed only at a site of the electron transit layer 3 (and the spacer layer 4) which is aligned with and below the gate electrode 9. The p-type semiconductor region 10a is locally high in p-type impurity concentration (Mg concentration) both in a current conduction direction and in a stack direction of GaN crystals.

Since the etching of the electron transit layer 3 is unnecessary when forming the p-type semiconductor region 10a, the sheet resistance and the contact resistance are reduced to achieve a stable operation.

In this embodiment, the above structure allows 2DEG to disappear only at a site of the p-type semiconductor region 10a so as to surely achieve Normally Off.

In the electron transit layer 3, the p-type semiconductor region 10a is formed only at a site which is contained in a region below the gate electrode 9. Since the protective layer 6 and the electron supply layer 5 directly under the gate electrode 9 contain no p-type impurity, the on-voltage can be controlled to an appropriate value, thereby greatly improving the element reliability.

As described above, in this embodiment, a highly reliable MIS-type AlGaN/GaN HEMT is realized which reduces the sheet resistance and the contact resistance to stabilize the operation and improve the device performance so as to surely achieve Normally Off.

### Fifth Embodiment

This embodiment discloses an AlGaN/GaN HEMT as a compound semiconductor device as in the first embodiment but is different from the first embodiment in that the formation method of the p-type semiconductor region is different.

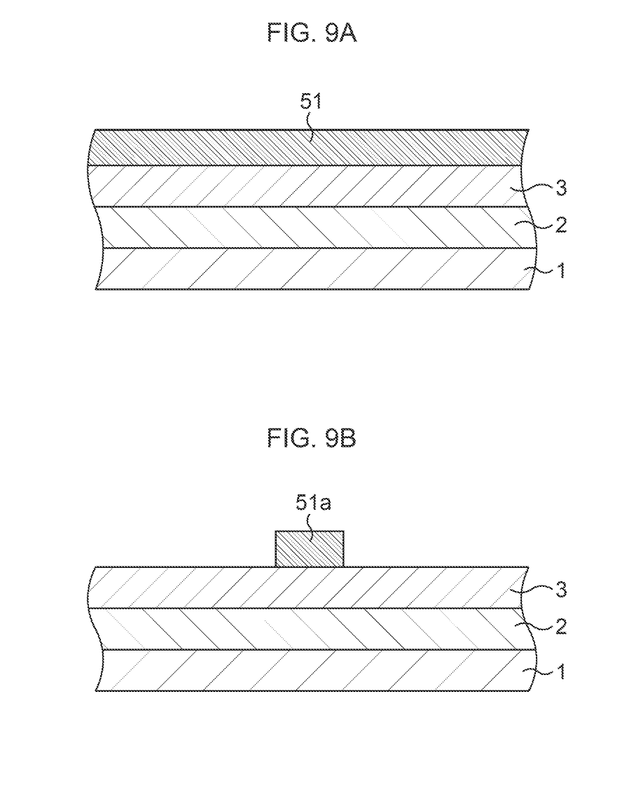

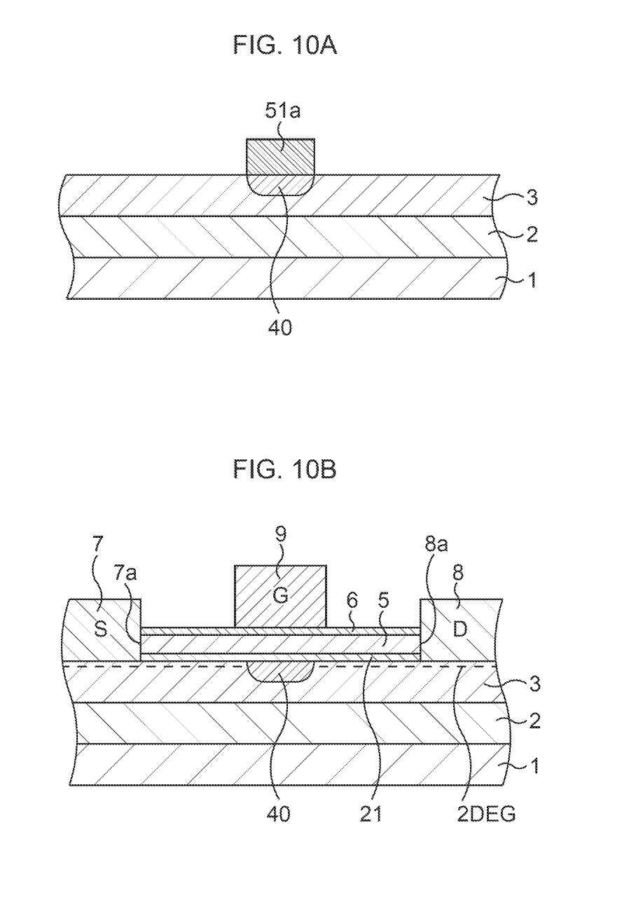

FIG. 9A and FIG. 9B and FIG. 10A and FIG. 10B are schematic cross-sectional views illustrating main processes in a method of manufacturing the AlGaN/GaN HEMT according to a fifth embodiment.

First, as illustrated in FIG. 9A, a buffer layer 2 and an electron transit layer 3 are formed in order on, for example, a Si substrate 1, and a MgO layer 51 is further formed.

More specifically, on the Si substrate 1, layers of the following compound semiconductors are epitaxially grown by, for example, an MOVPE method. An MBE method or the like may be used instead of the MOVPE method.

The buffer layer 2 is formed by growing AlN to a thickness of, for example, about 10 nm to 2000 nm on the Si substrate 1. The electron transit layer 3 is formed by growing i(intentionally undoped)-GaN to a thickness of, for example, about 1000 nm to 3000 nm.

For growth of AlN, mixed gas of TMAl gas being an Al source and NH₃ gas is used as a source gas. For growth of GaN, mixed gas of TMGa gas being a Ga source and NH₃ gas is used as a source gas. According to the compound semiconductors to be grown, whether or not to supply the TMAl gas and the TMGa gas and flow rates thereof are appropriately set. The flow rate of the NH₃ gas being a common source is set to about 100 sccm to about 100 slm. Further, growth pressure is set to about 50 Torr to about 300 Torr, and growth temperature is set to about 800° C. to about 1200° C.

Next, a compound layer of a p-type impurity, here, the MgO layer 51 is formed on the electron transit layer 3.

Subsequently, MgO is deposited, on the electron transit layer 3, to a thickness of about 50 nm, for example, by the vapor deposition method. Thus, the MgO layer 51 is formed on the electron transit layer 3.

Subsequently, as illustrated in FIG. 9B, the MgO layer 51 is processed.

More specifically, silicon oxide (SiO₂) is formed on the MgO layer 51 and processed by lithography to form a SiO₂ mask that covers a predetermined site, smaller than the gate length, of a portion of the MgO layer 51 corresponding to a formation scheduled site for a gate electrode, and opens the other portion. Using the SiO₂ mask, wet etching is performed on the MgO layer 51. The wet etching is performed by immersion in sulfuric acid. By the wet etching, a portion of the MgO layer 51 exposed through the opening of the SiO₂ mask is etched and removed so that the MgO layer 51 remains at the predetermined site on the electron transit layer 3. The remaining MgO layer 51 is illustrated as 51a. The MgO layer 51a becomes a later-described diffusion source of Mg being a p-type impurity.

The SiO₂ mask is removed by wet treatment or the like.

MgO is a material desirably processable by wet etching. In this embodiment, the MgO layer 51 is processed by the wet etching without using dry etching. Therefore, the MgO layer 51a in a desired shape can be obtained without damaging the electron transit layer 3 due to etching. Note that in order to protect the GaN surface of the electron transit layer 3, a protective film of SiO₂ or the like may be formed on the electron transit layer 3 in a manner to cover the MgO layer 51a.

Subsequently, as illustrated in FIG. 10A, a p-type semiconductor region 40 is formed in the electron transit layer 3.

More specifically, the MgO layer 51a is thermally treated via a protective film 4. Treatment temperature is about 1000° C. and treatment time is about one hour. This thermal treatment diffuses Mg being the p-type impurity from the MgO layer 51a to the electron transit layer 3 below the MgO layer 51a. In this event, oxygen (O) is also diffused at the same time. Mg and O diffuse downward from the surface of the electron transit layer 3 in a range of the electron transit layer 3 aligned with the MgO layer 51a. Thus, the p-type semiconductor region 40 is formed in the electron transit layer 3.

The MgO layer 51a is removed by wet treatment or the like.

The p-type semiconductor region 40 is contained in a formation scheduled range for the gate electrode and formed to be appropriately narrower than the formation scheduled range. This enables two-dimensional electron gas (2DEG) only at a portion aligned with and under the gate electrode of the 2DEG to surely disappear in the AlGaN/GaN HEMT.

Subsequently, the formation processes, for example, in FIG. 4A to FIG. 4C of the second embodiment are performed in order. The state in this embodiment corresponding to that in FIG. 4C is illustrated in FIG. 10B. The thermal treatment in the regrowth process in FIG. 4A promotes activation of Mg in the p-type semiconductor region 40.

Thereafter, through processes such as forming wirings connected to the source electrode 7, the drain electrode 8, and the gate electrode 9 and so on, the AlGaN/GaN.HEMT according to this embodiment is formed.

In this embodiment, the p-type semiconductor region 40 that raises the energy band is disposed only at a site of the electron transit layer 3a which is aligned with and below the gate electrode 9. The p-type semiconductor region 40 is locally high in p-type impurity concentration (Mg concentration) both in a current conduction direction and in a stack direction of GaN crystals.

Since the etching of the electron transit layer 3 is unnecessary when forming the p-type semiconductor region 40, the sheet resistance and the contact resistance are reduced to achieve a stable operation.

In this embodiment, the above structure allows 2DEG to disappear only at a site of the p-type semiconductor region 40 so as to surely achieve Normally Off.

In the electron transit layer 3, the p-type semiconductor region 40 is formed only at a site which is contained in a region below the gate electrode 9. Since the protective layer 6 and the electron supply layer 5 directly under the gate electrode 9 contain no p-type impurity, the on-voltage can be controlled to an appropriate value, thereby greatly improving the element reliability.

As described above, in this embodiment, a highly reliable AlGaN/GaN HEMT is realized which reduces the sheet resistance and the contact resistance to stabilize the operation and improve the device performance so as to surely achieve Normally Off.

### Sixth Embodiment

This embodiment discloses a power supply device to which one kind selected from among the AlGaN/GaN HEMTs of the first to fifth embodiments is applied.

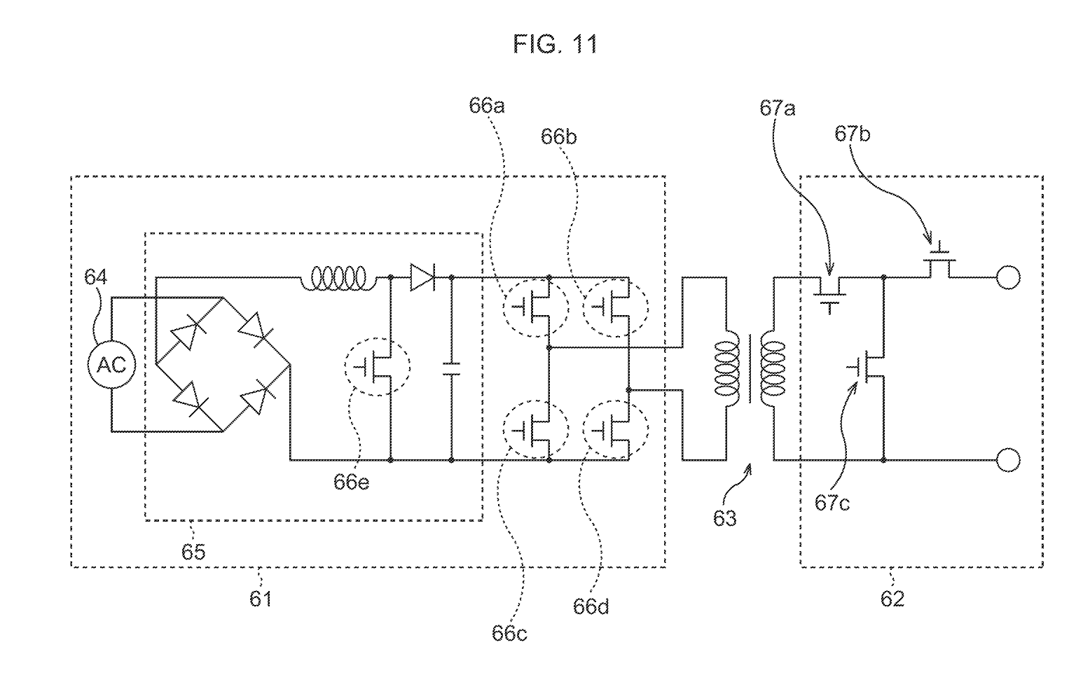

FIG. 11 is a connection diagram illustrating a schematic configuration of a power supply device according to a sixth embodiment.

The power supply device according to this embodiment includes a high-voltage primary-side circuit 61, a low-voltage secondary-side circuit 62, and a transformer 63 disposed between the primary-side circuit 61 and the secondary-side circuit 62.

The primary-side circuit 61 includes an AC power supply 64, a so-called bridge rectifying circuit 65, and a plurality of (four here) switching elements 66a, 66b, 66c, 66d. Further, the bridge rectifying circuit 65 has a switching element 66e.

The secondary-side circuit 62 includes a plurality of (three here) switching elements 67a, 67b, 67c.

In this embodiment, the switching elements 66a, 66b, 66c, 66d, 66e of the primary-side circuit 61 are each one kind selected from among the AlGaN/GaN HEMTs of the first to fifth embodiments. On the other hand, the switching elements 67a, 67b, 67c of the secondary-side circuit 62 are each an ordinary MIS.FET using silicon.

In this embodiment, a highly reliable high-withstand-voltage AlGaN/GaN HEMT which reduces the sheet resistance and the contact resistance to stabilize the operation and improve the device performance so as to surely achieve Normally Off is applied to a high-voltage circuit. This realizes a highly reliable large-power power supply circuit.

### Seventh Embodiment

This embodiment discloses a high-frequency amplifier including one kind selected from among the AlGaN/GaN HEMTs of the first to fifth embodiments.

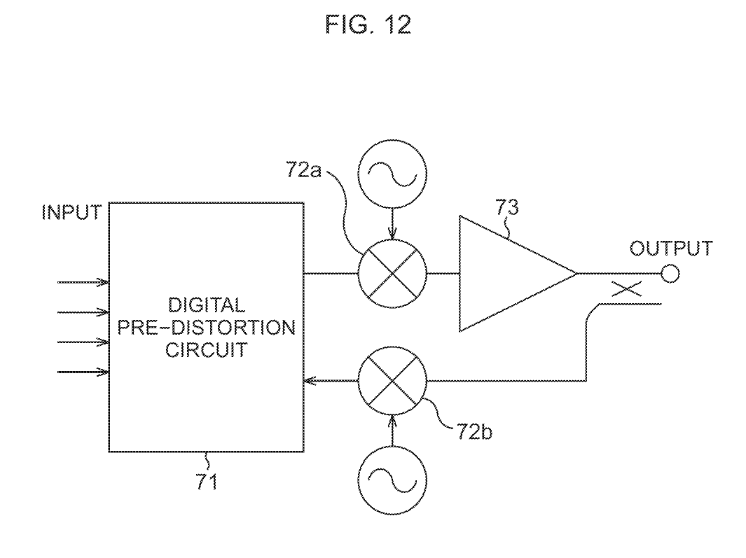

FIG. 12 is a connection diagram illustrating a schematic configuration of a high-frequency amplifier according to a seventh embodiment.

The high-frequency amplifier according to this embodiment includes a digital pre-distortion circuit 71, mixers 72a, 72b, and a power amplifier 73.

The digital pre-distortion circuit 71 compensates nonlinear distortion of an input signal. The mixer 72a mixes the input signal whose nonlinear distortion is compensated and an AC signal. The power amplifier 73 amplifies the input signal mixed with the AC signal, and has one kind selected from among the AlGaN/GaN HEMTs of the first to fifth embodiments. In FIG. 12, by, for example, changing the switches, an output-side signal can be mixed with the AC signal by the mixer 72b, and the resultant can be sent out to the digital pre-distortion circuit 71.

In this embodiment, a highly reliable high-withstand-voltage AlGaN/GaN HEMT which reduces the sheet resistance and the contact resistance to stabilize the operation and improve the device performance so as to surely achieve Normally Off is applied to a high-frequency amplifier. This realizes a highly reliable high-withstand-voltage high-frequency amplifier.

### Other Embodiments

In the first to seventh embodiments, the AlGaN/GaN HEMTs are exemplified as the compound semiconductor devices. Other than the AlGaN/GaN HEMTs, the following HEMTs are applicable as the compound semiconductor devices.

### Other HEMT Example 1

This example discloses an InAlN/GaN HEMT as a compound semiconductor device.

InAlN and GaN are compound semiconductors whose lattice constants can be made close to each other by their compositions. In this case, in the above-described first to seventh embodiments, the electron transit layer is formed of i-GaN, the electron supply layer is formed of i-InAlN, and the protective layer is formed of n-GaN. The spacer layer is formed in a stacked structure composed of a lower layer formed of thin i-AlGaN and an upper layer formed of i-InAlN, or a single layer of AlN. Since piezoelectric polarization barely occurs in the InAlN/GaN HEMT, 2DEG mainly occurs by spontaneous polarization of InAlN.

According to this example, a highly reliable high-withstand-voltage InAlN/GaN HEMT is realized which stabilizes the operation and improves the device performance to surely achieve Normally Off as in the above-described AlGaN/GaN.HEMTs.

### Other HEMT Example 2

This example discloses an InAlGaN/GaN HEMT as a compound semiconductor device.

GaN and InAlGaN are compound semiconductors that the lattice constant of the latter can be made smaller than the lattice constant of the former by their compositions. In this case, in the above-described first to seventh embodiments, the electron transit layer is formed of i-GaN, the electron supply layer is formed of i-InAlGaN, and the protective layer is formed of n-GaN. The spacer layer is formed in a stacked structure composed of a lower layer formed of thin i-AlGaN and an upper layer formed of i-InAlGaN, or a single layer of AlN.

According to this example, a highly reliable high-withstand-voltage InAlGaN/GaN HEMT is realized which stabilizes the operation and improves the device performance to surely achieve Normally Off as in the above-described AlGaN/GaN.HEMTs.

According to the above aspects, a highly reliable compound semiconductor device is realized which reduces resistance to stabilize the operation and improve the device performance so as to surely achieve Normally Off.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device, comprising:
an electron transit layer;
an electron supply layer formed above the electron transit layer; and
an electrode formed above the electron supply layer,
wherein a p-type semiconductor region is formed only at a site of the electron transit layer which is contained in a region below the electrode.

2. The compound semiconductor device according to claim 1,
wherein the p-type semiconductor region is formed narrower in width than the electrode.

3. The compound semiconductor device according to claim 1,
wherein the p-type semiconductor region has an upper surface formed in a surface of the electron transit layer.

4. The compound semiconductor device according to claim 1, further comprising:
a spacer layer between the electron transit layer and the electron supply layer.

5. The compound semiconductor device according to claim 4,
wherein the p-type semiconductor region is formed in the electron transit layer and the spacer layer, and
wherein a portion of the spacer layer in the p-type semiconductor region is lower in p-type impurity concentration than a portion of the electron transit layer in the p-type semiconductor region.

6. The compound semiconductor device according to claim 1,
wherein the p-type semiconductor region has an upper surface formed at a site away from the surface of the electron transit layer in a depth direction.

7. The compound semiconductor device according to claim 1, further comprising:
a protective layer between the electron supply layer and the electrode.

8. The compound semiconductor device according to claim 7, further comprising:
a gate insulating film between the protective layer and the electrode.

9. A method of manufacturing a compound semiconductor device, comprising:
forming an electron transit layer;
forming a p-type semiconductor region only at an electrode formation scheduled site of the electron transit layer;
forming an electron supply layer above the electron transit layer; and
forming an electrode at a site above the electron supply layer which contains the p-type semiconductor region.

10. The method of manufacturing a compound semiconductor device according to claim 9,
wherein the p-type semiconductor region is formed narrower in width than the electrode.

11. The method of manufacturing a compound semiconductor device according to claim 9,
wherein the p-type semiconductor region has an upper surface formed in a surface of the electron transit layer.

12. The method of manufacturing a compound semiconductor device according to claim 9, further comprising:
forming a spacer layer between the electron transit layer and the electron supply layer.

13. The method of manufacturing a compound semiconductor device according to claim 12,
wherein the p-type semiconductor region is formed in the electron transit layer and the spacer layer, and
wherein a portion of the spacer layer in the p-type semiconductor region is lower in p-type impurity concentration than a portion of the electron transit layer in the p-type semiconductor region.

14. The method of manufacturing a compound semiconductor device according to claim 9,
wherein the p-type semiconductor region has an upper surface formed at a site away from the surface of the electron transit layer in a depth direction.

15. The method of manufacturing a compound semiconductor device according to claim 9, further comprising:
forming a protective layer between the electron supply layer and the electrode.

16. A power supply circuit comprising a transformer, and a high-voltage circuit and a low-voltage circuit across the transformer,
the high-voltage circuit comprising a transistor,
the transistor comprising:
an electron transit layer;
an electron supply layer formed above the electron transit layer; and
an electrode formed above the electron supply layer,
wherein a p-type semiconductor region is formed only at a site of the electron transit layer which is contained in a region below the electrode.
